(19) United States
(12) Patent Application Publication
(10) Pub. No.: US 2025/0040204 A1
(43) Pub. Date: Jan. 30, 2025

(54) TRANSISTOR WITH BODY CONTACT IMPLANT HAVING IMPROVED SHAPE, AND MANUFACTURING METHOD THEREOF

(71) Applicant: STMicroelectronics International N.V., Geneva (CH)

(72) Inventors: Giuseppe Pio PISA, Milano (IT); Riccardo DEPETRO, Domodossola (IT)

(73) Assignee: STMicroelectronics International N.V., Geneva (CH)

(21) Appl. No.: 18/774,272

(22) Filed: Jul. 16, 2024

(30) Foreign Application Priority Data
Jul. 25, 2023 (IT) 102023000015612

(51) Int. Cl. H01L 29/06; H01L 27/088; H01L 29/10; H01L 29/417; H01L 29/66; H01L 29/78

(52) U.S. Cl. CPC H01L 29/0692; H01L 29/1095; H01L 29/66568; H01L 29/78; H01L 27/088; H01L 29/41758

(57) ABSTRACT

Electronic device, comprising: a semiconductor body having a surface, an electrical conductivity P and a first doping value; at least one gate region on the surface; one or more source regions, having a second electrical conductivity N, extending in the semiconductor body at the surface and at a first side of the gate region; and at least one body contact region, of P+ type, extending in the semiconductor body at the surface and at the first side of the gate region 22. The first gate region has the shape of a stripe with main extension along a first direction. The first body contact region has a tapered shape along said first direction. The one or more source regions are adjacent to, and at least partially surround, the first body contact region.

### BACKGROUND

### Technical Field

The present disclosure relates to an electronic device and manufacturing method thereof, and more particularly to the manufacturing of a body contact region of a transistor.

### Description of the Related Art

Silicon power MOSFETs are widely used in modern electronic devices, especially for switching applications. One of the main merit/quality parameters is the on-state resistance (Ron) multiplied by the area (A) which considers both the intrinsic electrical conduction loss (due, in fact, to the resistance Ron) and the occupied area. It is therefore advisable to reduce the factor Ron. A by acting on the factor A without affecting the electrical performances and the robustness of the device, in particular the robustness during breakdown phenomena. In this latter case, it is common to use the figure of merit (robustness parameter) BV_{ON} (on-state breakdown).

FIG. 1 shows, in top-view and in a triaxial reference system of axes X, Y, Z orthogonal to each other, a portion of a MOSFET device 1 of known type, having horizontal conduction. The MOSFET device 1 comprises a semiconductor body 10 (e.g., Silicon), which is P− type doped. Gate regions 2 are formed on the semiconductor body 10, for example in polysilicon, electrically insulated from the semiconductor body 10 by a gate dielectric (not illustrated). In the semiconductor body 10 there extend: source regions 4 at a respective side of the gate regions 2, formed by N+ type implants in the semiconductor body 10; drain regions 6 extending at a respective side of the gate regions 2, opposite to the side at which the respective source regions 4 extend, formed by N+ type implants in the semiconductor body 10; and a body contact region 8, extending between, and adjacent to, the source regions 4, formed by a P+ type implant in the semiconductor body 10.

As may be observed from FIG. 1, the gate 2, source 4, drain 6 and body contact 8 regions have, in top-view, the shape of bands or stripe, with main extension along the Y-axis, and alternate with each other along the X-axis direction.

A silicide layer is formed, at the source 4 and body contact 8 stripes, thereabove, which extends uniformly on the source 4 and body contact 8 regions, contacting them electrically. Similarly for the drain regions 6. For example, a metal silicide, such as for example a silicide of Ni, Ti, Co, Pt, Ta, may be used.

A protection and electrical insulation layer extends, in a manner not illustrated in the Figure, above the gate 2, source 4, drain 6 and body contact 8 regions. In order to establish an electrical contact to bias, during use, the source 4 and body contact 8 regions, metal contacts or “plugs” are formed which extend along the Z-direction through trenches or openings formed in the protection and electrical insulation layer, up to electrically contacting surface portions of the silicide layer. These plugs are illustrated in the Figure schematically and in dashed line, and identified with the reference numeral 9. Similarly for the drain regions 6.

The solution of FIG. 1 does not allow further scalability of the opening of the distance de comprised between two gate regions 2 directly facing each other along X, owing to limits due to the photolithographic and implant resolution. For example, de has a value comprised between 0.6 and 1.2 μm (range boundary values included).

A possible known solution, which allows the distance value de of FIG. 1 to be reduced, is shown in FIG. 2, wherein elements common to FIG. 1 are illustrated with the same reference numerals and not further described. Unlike what has been illustrated in FIG. 1, the body contact region 8 does not extend in the form of a stripe but has discontinuous (P+ doped) body contact sub-regions 12, which alternate with a certain periodicity along the Y-axis. In this case, therefore, P+ regions (the body contact sub-regions 12) alternate with N+ regions (the source regions 4) along the Y-direction. The P+ sub-regions 12 extend, along the X-direction, throughout the entire dimension de′. Unlike the solution of FIG. 1, where the P+ sub-regions 12 are present, corresponding source regions 4 are not present between these P+ sub-regions 12 and the gate regions 2. Therefore, in FIG. 2, also the source regions 4 do not extend in the form of a stripe, but have discontinuous sub-regions, which alternate with a respective periodicity along the Y-axis and have, where present, dimension d_{B}′<d_{B} along the X-axis. For example, d_{B}′ has a value comprised between 0.4 and 0.8 μm (range boundary values included).

According to the solution of FIG. 2, the area A of a low-voltage power device (e.g., between 5V and 20V, in particular 5V, 8V, 12V, 16V) may be reduced. The electrical performances are considerably modulated by the number of P+ sub-regions 12. This solution ensures limited global advantages, as the effect on the two main merit/quality parameters cannot be decoupled: the parameter Rₒₙ·A is allowed by a high area occupation by the N+ source regions, while the parameter BV_{ON} is allowed by a high area occupation by the P+ contact regions. In general, the parameter Ron specific per unit of length (Rₒₙ·W) worsens as regions facing between drain and source are inhibited from conduction due to the absence of source regions directly facing the corresponding drain, if a P+ region 12 is present. Only in case the distance between the P+ regions 12 were sufficiently high would the saving in area obtained thanks to the reduction of the parameter de′ allow a better figure of merit Rₒₙ·A. An excessive distance between the P+ regions 12, however, would lead to a degradation of the figure of merit BV_{ON} withstandable by the device.

The present disclosure provides an electronic device and manufacturing method thereof which overcomes the aforementioned issues.

### BRIEF SUMMARY

According to the present disclosure, an electronic device and manufacturing method thereof are provided. A device includes a semiconductor body having a first electrical conductivity, and a first doping value. A first surface on the semiconductor body is between a first gate region and a second gate region, the first surface having a first edge at the first gate region. A plurality of source regions is on the first surface. Each source region has a second electrical conductivity opposite to the first electrical conductivity, extending in a first direction traverse to the first surface, and for a first depth. A plurality of body contact regions is on the first surface. Aach body contact region has the first electrical conductivity and a second doping value greater than the first doping value, extending in the first direction for a second depth greater than the first depth. The plurality of body contact regions contact the first edge at a plurality of first vertices and the plurality of source regions contacts the entire first edge except the plurality of first vertices.

### BRIEF DESCRIPTION OF THE SEVERAL VIEWS OF THE DRAWINGS

For a better understanding of the present disclosure, preferred embodiments thereof are now described, purely by way of non-limiting example, with reference to the attached drawings, wherein:

FIG. 1 illustrates, in top-plan view, a portion of a horizontal conduction MOSFET according to a known embodiment;

FIG. 2 illustrates, in top-plan view, a portion of a horizontal conduction MOSFET according to a further known embodiment;

FIGS. 3A to 7 illustrate, in top-plan view, respective portions of an electronic device, in particular a lateral (or horizontal) conduction MOSFET, according to respective embodiments of the present disclosure;

FIG. 8 illustrates, in cross-sectional view, the electronic device of FIGS. 3A-7 according to an embodiment of the present disclosure;

FIGS. 9A and 9B illustrate, according to respective plan and perspective views, an implant mask to partially form the electronic device of FIGS. 3A-8; and

FIGS. 10A and 10B illustrate, according to respective plan and perspective views, a further implant mask to partially form the electronic device of FIGS. 3A-8.

### DETAILED DESCRIPTION

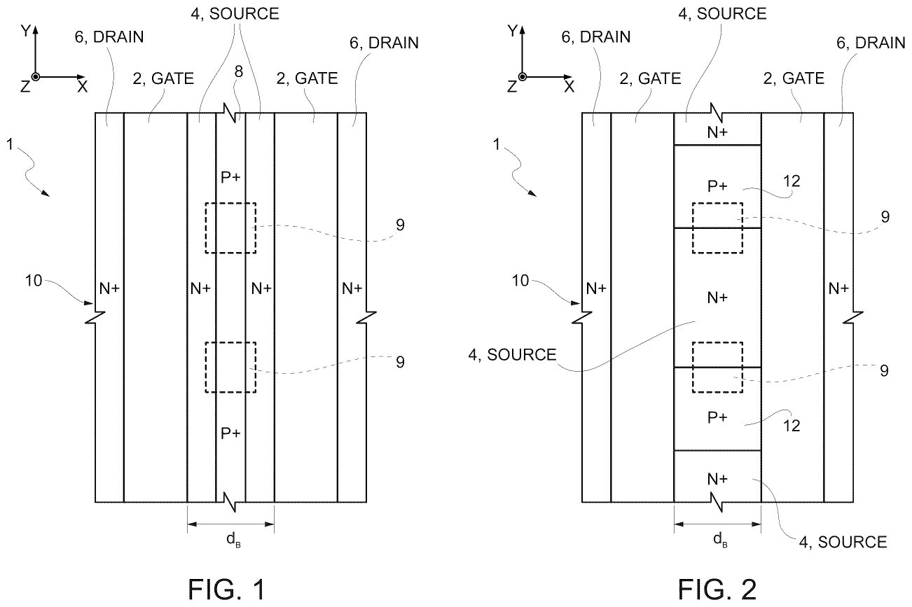

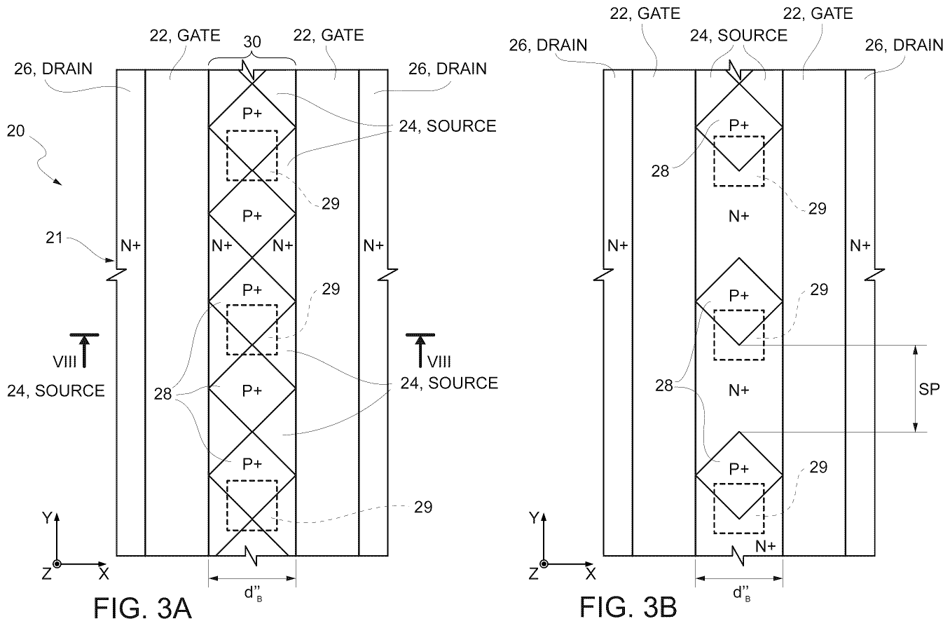

FIG. 3A illustrates, in top-plan view (on the XY-plane) in the same reference system as FIGS. 1 and 2, a portion of an electronic device 20, in particular a transistor, such as a horizontal channel MOSFET, according to one aspect of the present disclosure.

The device 20 comprises:
a semiconductor body 21, for example of Silicon or Silicon Carbide, P-type doped and having a front side 21a opposite to a rear side along the Z-axis direction;
a gate electrode, forming a control terminal of the device 20, including gate regions 22 which extend on the front side 21a. Each gate region 22 comprises a gate dielectric and a gate conductive region on the gate dielectric;
a first conduction terminal, including source regions 24, in particular regions implanted in the semiconductor body 21 at the front side 21a, at a respective side of a respective gate region 22. Each source region 24 has N-type doping, with a N+ peak concentration for example comprised between 5·10¹⁹−2·10²¹ (range boundaries included);
a second conduction terminal, including drain regions 26, in particular regions implanted in the semiconductor body 21 at the front side 21a, at a respective side of a respective gate region 22. For each gate region 22, the drain regions 26 extend at one side of the respective gate region 22 which is opposite to the side at which the respective source regions 24 extend.

As may be observed from FIG. 3A, the gate 22 and drain 26 regions have, in top-view, the shape of bands or stripe, with main extension along the Y-axis, and alternate with each other along the X-axis direction. The gate 22 and drain 26 regions extend parallel to each other.

Gate regions 22 facing each other along the X-direction are spaced from each other by an amount d_{B}″, having a value, along the X-axis direction, comprised between 0.4 and 0.8 μm (range boundaries included), for example equal to 0.45 μm. The portion of the device 20 comprised (in the plan-view of FIG. 3A) between two gate regions 22 facing each other along the X-direction is identified with the reference numeral 30. Therefore, the dimension along the X-direction of the portion 30 is equal to d_{B}″, while along the Y-axis direction the portion 30 has the shape of a band or stripe and extends parallel to the gate 22 and drain 26 regions.

The source regions 24 are completely contained within the portion 30.

The semiconductor body 21 has, for example, a peak concentration of the N-type dopant of a value comprised between 5·10¹⁶ and 1·10¹⁸ at/cm³ (ends of range included).

Body contact regions 28 also extend within the portion 30. The body contact regions 28 are regions having P-type doping, with a P+ dopant density for example comprised between 5·10¹⁹ and 2·10²¹ at/cm³ (range boundaries included). The body contact regions 28 have a function similar to that of the contact regions 8 previously described.

A silicide layer (not illustrated) extends, at the portion 30, i.e., above and in electrical contact with the source 24 and body contact 280 regions, uniformly on the source 24 and body contact 28 regions. For example, a metal silicide, such as for example a silicide of Ni, Ti, Co, Pt, Ta, may be used. Similarly, the drain regions 26 may also have, thereabove, a corresponding silicide layer.

A protection and electrical insulation layer extends, in a manner not illustrated in FIG. 3A, above the gate 22, source 24, drain 26 and body contact 28 regions. In order to establish an electrical contact to bias, during use, the source terminal and the body, metal contacts or “plugs” are formed which extend along the Z-axis direction through trenches or openings formed in this protection and electrical insulation layer, up to electrically contacting surface portions of the silicide layer in the portion 30. These plugs are illustrated in the Figure in a schematic manner and in dashed line, and identified with the reference numeral 29. Similarly, for the drain regions 26 one or more metal contacts or “plugs” may be present to bias, in use, the drain terminal.

According to one aspect of the present disclosure, the body contact regions 28 have a tapered shape along the Y-axis direction, for example with dimension (along the X-axis) of progressively reduced value moving along at least one positive or negative Y-axis direction.

More specifically, each (or at least one) body contact region 28 has a first dimension, considered along the X-axis at a first height along the Y-axis, having a first value and a second dimension, again considered along the X-axis but at a second height (different from the first height) along the Y-axis, having a second value lower than the first value. In other words, the width considered along the X-axis of the body contact region(s) 28 decreases progressively or discretely as it moves along the Y-axis direction.

The tapered shape of the body contact region(s) 28 may be present along both the positive and negative Y-axis directions, or along only one direction (only positive or only negative) of the Y-axis (for example in the case of region 28 having, in top-view, triangular shape).

According to one aspect of the present disclosure, the body contact regions 28 are arranged in succession to each other, along the Y-axis direction and have a polygonal shape and orientation such as to maximize the extension of the N+ implants of source 24 that are in direct correspondence of, or are facing, the gate regions 22. To this end, the body contact regions 28 extend up to the gate regions 22 at a vertex (or corner) of the polygon which determines their shape, so that along the sides of the gate regions 22 the extension area (similarly, volume) of the N+ implant of the source regions 24 prevails, as a percentage, with respect to the corresponding extension area (or volume) of the P+ implant of the body contact regions 28. With respect to the embodiment of FIG. 2, the periodicity (number) of the body contact regions 28, which in the embodiment of FIG. 3A are arranged adjacent to each other along the Y-axis direction, or separated from each other, again along Y, may also be maximized by an amount freely chosen according to project requirements (e.g., as small as desired).

In particular, the body contact regions 28 have, in FIG. 3A, a rotated square shape (in the embodiment represented, rotated by 45° with respect to the Y-axis or the X-axis) or, if observed on the XY-plane along the Y-axis direction, a rhomboidal shape. These body contact regions 28 therefore have four vertices, wherein two vertices are opposite to each other along the X-direction and lie at the ends of a first diagonal of the square (or rhombus), said first diagonal being parallel to the X-axis; and wherein the other two vertices are opposite to each other along the Y-direction and lie at the ends of a second diagonal of the square (or rhombus), said second diagonal being parallel to the Y-axis and orthogonal to the first diagonal. Along the Y-axis, body contact regions 28 immediately successive to each other are also adjacent to each other at the respective vertices lying at the ends of the second diagonal. The aforementioned first diagonal has a maximum width equal to the width d_{B}″ of the portion 30.

In general, the first diagonal of the rhombus may form, with the Y-axis direction, an angle greater than 0° and smaller than 90°.

Since body regions 28 immediately successive to each other along the Y-axis direction have respective vertices adjacent to each other, they form, as a whole and from an electrical point of view, a single body region.

In case it is desired to keep the value of the angles of the quadrilateral that forms the regions 28 fixed (by design) at a value of 90° (rotated square), the minimum value of d_{B}″ is equal to the value of the first diagonal (which in turn is equal to the value of the second diagonal). In absence of this constraint, the value of the second diagonal may be increased with respect to the value of the first diagonal, reducing the value d_{B}″ correspondingly.

Variations to FIG. 3A are possible, in particular, as illustrated in FIG. 3B, the rhomboidal regions described above may not be adjacent to each other along the Y-axis direction, but separated by respective N+ source regions 24. In this case, the body contact regions 28 are arranged in succession with a cadence defined in the design step. For example, they may be separated, along Y, by an amount SP comprised between 0.15 and 1 μm (range boundaries included), for example equal to 0.18 μm.

The value of SP, i.e., the spacing between the various regions 28, may be uniform along the entire portion 30, or it may vary within the range indicated above (i.e., regions 28 successive to each other along Y may be separated by a different distance SP with respect to other regions 28 successive to each other along Y).

Elements of FIG. 3B common to FIG. 3A are illustrated with the same reference numerals and are not further described.

In a further embodiment, not illustrated, the aforementioned first diagonal has a maximum width lower than the width d_{B}″ of the portion 30. This embodiment may be combined both with the embodiment of FIG. 3A (which provides for a succession of body contact regions 28 adjacent to each other along Y), and with the embodiment of FIG. 3B (which provides for a succession of body contact regions 28 separated from each other along Y by the amount SP).

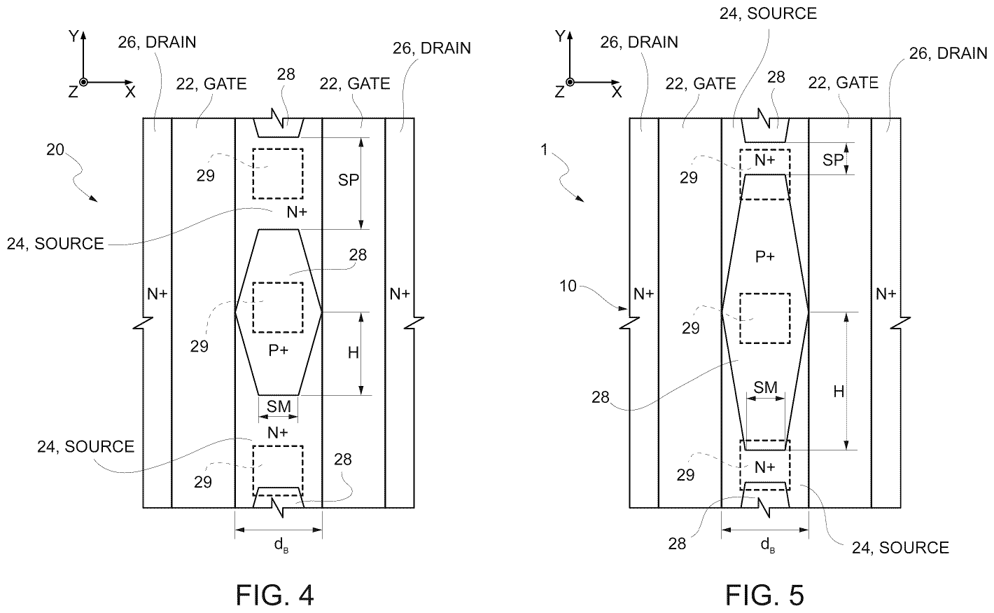

FIG. 4 illustrates a further embodiment wherein elements common to FIGS. 3A and 3B are illustrated with the same reference numerals and are not further described. In FIG. 4, the body contact regions 28 have a hexagonal shape with a maximum width equal to the width d_{B}″ of the portion 30. This maximum width occurs at two vertices opposite to each other, which represent the ends of a diagonal of the hexagon parallel to the X-axis.

In FIG. 4, the hexagonal body contact regions 28 are spaced (in particular, equally spaced) to each other along the Y-axis direction by an amount SP, in particular having a value in the aforementioned range with reference to FIG. 3A. As may be noted, the hexagon of FIG. 4 is not equilateral, but has four sides having a first length value (i.e., the sides which include the two vertices located at the gate regions 22), and the remaining two sides having a second length value (SM) lower than the first length value. The aforementioned four longer sides may also be characterized by a length value H which represents the projection of these sides on the Y-axis; the aforementioned two shorter sides may similarly be characterized by a length value (here coincident with SM) which represents the projection of these sides on the X-axis. When SM=0, the hexagon collapses into a quadrilateral (rotated square or rhombus), implementing the embodiment of FIG. 3B.

The values of SM are, for example, in the range 0.15-0.6 μm (boundaries included); the values of H are, for example, in the range 0.4-3μ, (boundaries included).

In a non-limiting example, with reference to FIG. 4, the proportion between SP and H is equal to about 50%.

FIG. 5 illustrates a further embodiment wherein elements common to FIGS. 3A-4 are illustrated with the same reference numerals and are not further described. In FIG. 5, the body contact regions 28 have a hexagonal shape similarly to what has been described and illustrated with reference to FIG. 4. However, in this case, the value of H is increased, and the value SP is reduced, so that the proportion between SP and H is lower than 50% (value of SP lower than value of H), for example equal to 10%.

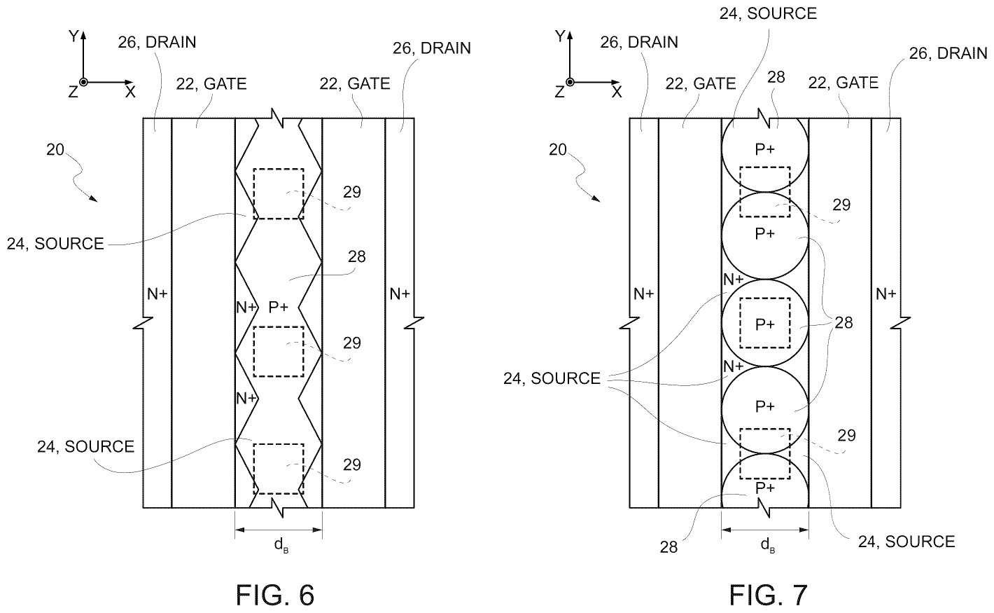

FIG. 6 illustrates a further embodiment wherein elements common to the preceding Figures are illustrated with the same reference numerals and are not further described. In FIG. 6, the body contact regions 28 have a hexagonal shape similarly to what has been described and illustrated with reference to FIG. 4 or FIG. 5 but, in this case, the value of SP has been reduced to zero, i.e., the body contact regions 28 are adjacent to each other and are arranged in succession seamlessly (similarly to FIG. 3A, taking into consideration the corresponding differences in shape).

FIG. 7 illustrates a further embodiment wherein elements common to the preceding Figures are illustrated with the same reference numerals and are not further described. In FIG. 7, the body contact regions 28 have a circular shape and are arranged in succession along Y tangent to each other, in a similar manner to what has been described with reference to FIG. 3A. Since the body regions 28 have an adjacent part they form, as a whole and from an electrical point of view, a single body region. A shape that is not perfectly circular, but oval, or generally rounded (e.g., rounded-off, closed curvilinear, round) is also possible.

In a manner not illustrated in the Figure, the circular (or oval, or rounded, or curvilinear) regions 28 may be spaced apart from each other along Y by the amount SP (not illustrated), in a similar manner to what has been described with reference to FIG. 3B.

The advantages of the embodiments previously described and illustrated in the Figures are summarized hereinbelow.

The solution of FIG. 3A maximizes the P+ doped surface. FIG. 3B reduces the area occupied by the regions 28 to simplify the manufacturing of the same (since forming the vertices of the regions 28 adjacent to each other along the Y-direction is not necessary). Similarly for FIG. 7, wherein the polygonal shapes of the regions 28 are replaced by circular shapes, which do not have vertices. The solutions of FIGS. 4, 5 and 6 are alternatives to those of FIGS. 3A and 3B, generalized to polygons whose shape (theoretically arbitrary) unbalances the area ratio between P+ implanted regions 28 and N+ implanted regions 24, in favor of the area occupied by the P+ regions 28.

It is evident that the geometric shapes illustrated in FIGS. 3A-7 may, in practice, vary due to the possible limitations of the manufacturing technology used (e.g., photolithography and ion implant); in particular, the regions 28 may have blurred and not perfectly defined outlines, and the vertices may not have a sharp corner shape, but a slightly rounded or beveled corner shape. The preceding description also applies to those situations wherein the geometric shapes are not ideal.

Moreover, the present disclosure overcomes the issues of the state of the art even in absence of ideal and perfectly defined geometric shapes of the regions 28. In fact, it is sufficient that each body contact region 28 (or the single body contact region 28 if a single region is present) has a tapered shape along the Y-axis direction, so as to minimize the facing surface (or volume) towards the gate regions 22, while optimizing the value of the ratio between the area occupied by the source regions 24 and the area occupied by the body contact regions 28 (i.e., optimizing the ratio between N+ regions and P+ regions). The Applicant has verified that this optimization is obtained with values of ratio between the area of the regions 24 and the area of the regions 28 (N+ area/P+ area) comprised between 1.5 and 5 (range boundaries included). In this context, the area values of the source regions 24 and of the body contact regions 28 are considered at the level of the upper surface 21a of the semiconductor body 21.

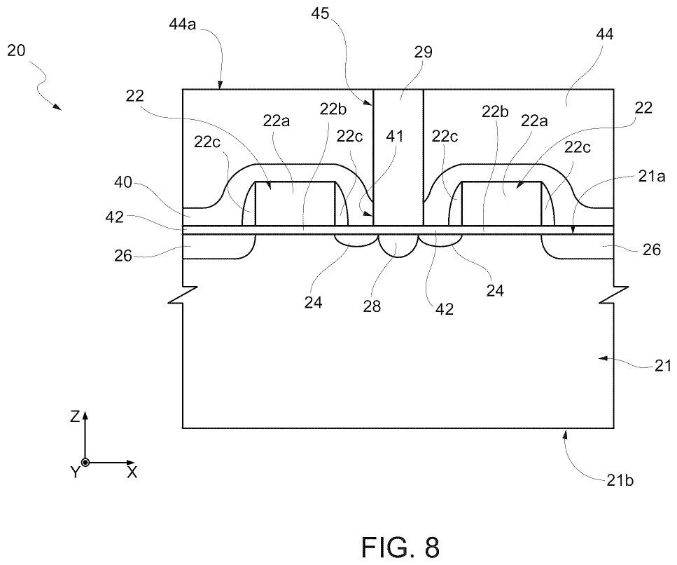

FIG. 8 illustrates, in cross-sectional view on the XZ-plane, the device 20, according to an embodiment of the present disclosure. Elements common to the preceding Figures are illustrated with the same reference numerals and are not further described.

The electronic device 20, comprising:
the semiconductor body 21 having the surface 21a opposite, along the Z-axis, to a surface 21b; the semiconductor body 21 has a first electrical conductivity (P) and a first doping value;
at least one gate region 22 (two gate regions 22 are illustrated for uniformity with the preceding embodiments), extending on the surface 21a;
one or more source regions 24, having a second electrical conductivity (N) opposite to the first electrical conductivity (P), extending in the semiconductor body 21 at the surface 21a and at a first side of the gate region 22; and
at least one body contact region 28, having the first electrical conductivity (P) and a second doping value higher than the first higher doping value, extending in the semiconductor body 2) at the surface 21a and at the first side of the gate region 22.

The first gate region 22 has the shape of a stripe with main extension along a first direction (Y).

The first body contact region 28 has a tapered shape along said Y-direction.

The one or more source regions 24 are adjacent to, and at least partially surround, the first body contact region 28.

In one embodiment, the body contact region 28 is aligned with, or at least partially superimposed on, the gate region 22 at the first side of the gate region 22.

In one embodiment, the body contact region 28 extends at a distance from the first side of the gate region 22 and the one or more source regions 24 extend between the body contact region 28 and the first side of the gate region 22.

In one embodiment, the body contact region 28 has a polygonal shape, including a quadrangular, pentagonal, hexagonal shape, and wherein a vertex of said polygonal shape faces, in particular faces directly, towards the gate region 22. The facing surface of the N+ source region 24 towards the gate region 22 (at the surface 21a) is maximized, allowing a constant low threshold to be obtained along the Y-direction and allowing the current to be collected without worsening the conduction losses.

In particular, in one embodiment, the body contact region 28 (or each body contact region 28 if more than one is present) is in lateral contact with the gate region 22 at the surface 21a.

In one embodiment, the body contact region 28 has a rhombus shape, wherein a first diagonal of said rhombus is orthogonal to the Y-direction, and a second diagonal of said rhombus is parallel to the Y-direction; alternatively, the body contact region 28 has a rhombus shape, wherein a first diagonal of said rhombus forms, with the Y-direction, an angle greater than 0° and smaller than 90°.

In one embodiment, the body contact region 28 has a circular or oval or closed curvilinear shape. The aforementioned advantages are also obtainable with this embodiment.

As already described previously, a further (second) body contact region 28 may be present or, in general, a plurality of body contact regions 28 may be present. The second body contact region 28 (as well as the further ones), has the first electrical conductivity (P) and the second doping value, extends in the semiconductor body 21 at the surface 21a and at the first side of the gate region 22, and has a tapered shape along the Y-axis direction.

The first and the second body contact regions 28 may extend adjacent to each other at a respective vertex.

The first and the second body contact regions 28 may extend at a distance SP from each other along the Y-direction and are separated from each other, along the Y-direction, by a source region 24.

The gate regions 22 each comprise, as already mentioned, a gate dielectric 22b and a gate conductive region 22a. The manufacturing process may optionally provide, in a per se known manner, for the formation of lateral spacers 22c, adjacent and contiguous to the gate conductive region 22a, on opposite sides of the same along the X-direction.

In case the spacers 22c are present, the value d_{B}″ (width along the X-axis of the portion 30) is considered from the sides, facing each other, of the gate conductive regions 22a (not from the spacers 22c possibly present).

A protection and electrical insulation layer 40, for example of SiO₂ or SiN, extends on the side 21a of the semiconductor body 21 and on the gate regions 22. The silicide layer (here identified with the reference numeral 42) extends above and in electrical contact with the source 24, body contact 28 and drain 26 regions. Openings 41 in the protection and electrical insulation layer 40 extend at the portion 30, up to reaching the silicide layer 42; a further insulating layer 44 extends above the protection and electrical insulation layer 40 and has corresponding openings 45 aligned with the openings 41. The openings 45 and 41 are filled with conductive material, in particular metal material, forming the plugs 29 which contact the regions 24 and 28 (through, as said, the silicide layer 42). The openings 41 and 45 may be completely filled by the conductive material, or only partially (e.g., along the inner lateral surfaces); in any case, this conductive material forms a continuous conductive path from the surface 44a of the layer 44 up to the silicide layer 42. The silicide layer 42 may be replaced with a different ohmic contact.

A process for manufacturing the source 24 and body contact 28 regions is now described, according to an embodiment of the present disclosure, and limitedly to these regions.

In detail, after having arranged the semiconductor body 21 and having formed the gate regions 22 (with the spacers 22c, if any), a masked implant step of the source regions 24 is performed.

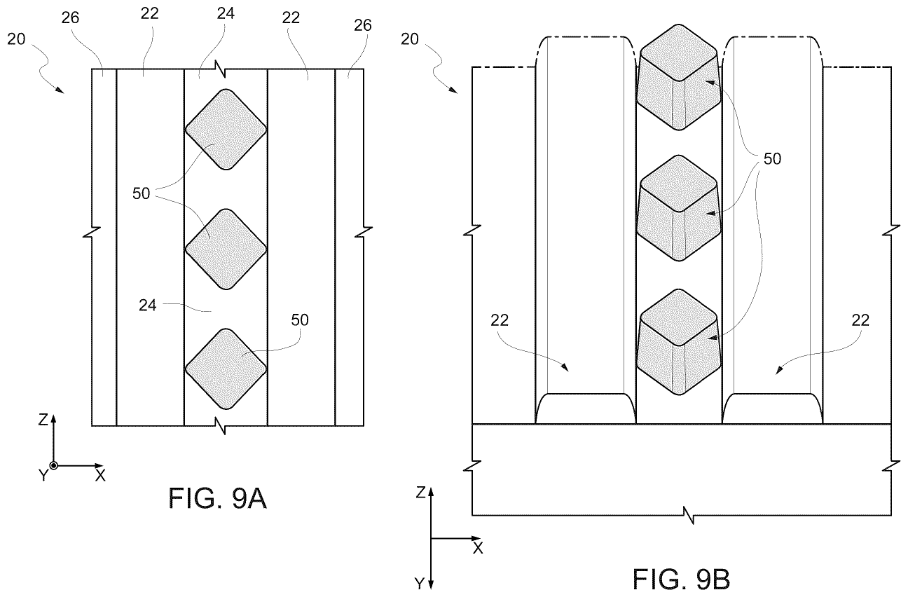

FIG. 9A corresponds to the embodiment of FIG. 3A, wherein the body contact regions 28 are covered by an implant mask 50, for example of photoresist, while the regions wherein it is desired to form the source 24 are exposed through openings in the mask 52. FIG. 9B is a perspective view of FIG. 9A. The implant mask 50 is formed by per se known photolithography steps and has, for example, a thickness, along Z, comprised between 0.25 and 2 μm (range boundaries included).

The process then proceeds with the implant of the N doping species, for example Arsenic, Phosphorus, Antimony or a combination thereof, using an implant dose comprised between 5·10¹³ and 5·10¹⁵ at/cm² (range boundaries included) and implant energy comprised between 5 and 100 keV (range boundaries included). The implant step forms the N-doped source regions at the portion 30 where the implant mask 50 is not present. In this same step the drain regions 26 may also be formed simultaneously.

Then, the mask 50 is removed and an implant mask 52 is formed which is complementary to the mask 50, i.e., designed to cover the implanted regions with N-type species (source 24 and drain 26 regions) in order to implant the body contact regions 28 of P-type.

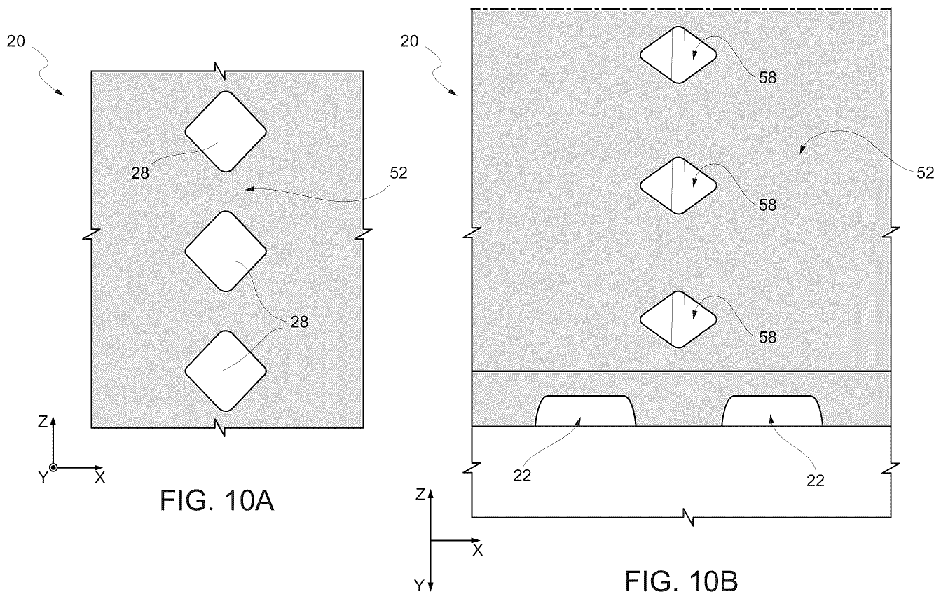

FIG. 10A illustrates, in plan-view on the XY-plane, the mask 52, which covers the previously-implanted N-type regions and leaves exposed the regions where it is desired to form the P-type implant (through the openings 58 in the mask 52). FIG. 10B is a perspective view of FIG. 10A.

The process then proceeds with the implant of the P doping species, for example Boron, Aluminum, Gallium, or a combination thereof, using an implant dose comprised between 5·10¹³ and 5·10¹⁵ at/cm² (range boundaries included) and implant energy comprised between 3 and 50 keV (range boundaries included).

Then, the mask 52 can be removed and the process proceeds with activation and diffusion steps of the implanted doping species (for example by annealing).

The steps described with reference to FIGS. 9A, 9B and 10A, 10B may be inverted to each other, i.e., it is possible to first form the mask 52 by implanting the body contact regions 28 and then form the mask 50 by implanting the source regions 24.

Then, the process may proceed with further manufacturing steps of the device 20, including the formation of the silicide layer 42, in a per se known manner.

Further manufacturing steps are not further described herein, as they are known and are not part of the present disclosure.

In a non-limiting embodiment, the mask 50 comprises a plurality of masking sub-regions having shape and extension equal to the shape and extension desired (designed) for the body contact regions 28; for example, each sub-region of the mask 50 is aligned (in top-view on the XY-plane) with the gate regions 22 at the sides of the gate regions 22 facing towards the portion 30.

In a non-limiting embodiment, the mask 50 comprises a plurality of masking sub-regions having shape and extension equal to the shape and extension desired (designed) for the body contact regions 28; for example each sub-region of the mask 50 extends at a distance from the sides of the gate regions 22, so that, after the implant steps, the source regions 24 extend between the body contact regions 28 and the gate regions 22.

In a non-limiting embodiment, the mask 50 comprises a plurality of masking sub-regions having shape and extension equal to the shape and extension desired (designed) for the body contact regions 28; for example, each sub-region of the mask 50 has a polygonal shape, including a quadrangular, pentagonal, hexagonal shape, and wherein a vertex of said polygonal shape faces directly towards the gate region 22.

In a non-limiting embodiment, the mask 50 comprises a plurality of masking sub-regions having shape and extension equal to the shape and extension desired (designed) for the body contact regions 28; for example, each sub-region of the mask 50 has, in top-view on the XY-plane, a rhombus shape, wherein a first diagonal of the rhombus is orthogonal to the Y-direction, and a second diagonal of said rhombus is parallel to the first Y-direction; alternatively, the mask 50 has rhombus shape, wherein a first diagonal of said rhombus forms, with the Y-direction, an angle greater than 0° and smaller than 90°.

In a non-limiting embodiment, the mask 50 has a circular or oval or closed curvilinear shape.

In a non-limiting embodiment, the mask 50 comprises a plurality of masking sub-regions having shape and extension equal to the shape and extension desired (designed) for the body contact regions 28; for example each sub-region of the mask 50 extends adjacent to another sub-region of the mask 50.

In a non-limiting embodiment, the mask 50 comprises a plurality of masking sub-regions having shape and extension equal to the shape and extension desired (designed) for the body contact regions 28; for example, each sub-region of the mask 50 is completely contained within the portion 30.

The device 21 may be one of the following (this list is exemplary and not limiting of the disclosure): MOSFET, LDMOSFET, DRIFTMOSFET.

From what has been previously discussed, the advantages which the present disclosure affords are evident.

In particular, the geometry adopted for the body contact 28 and source 24 region(s) allows the value of the parameter Rₒₙ·A to be reduced without negatively affecting the robustness of the device (i.e., without negatively affecting the parameter BV_{ON}).

Finally, it is clear that modifications and variations may be made to what has been described and illustrated herein without thereby departing from the scope of the present disclosure, as defined in the attached claims.

In particular, for all the embodiments exposed (FIGS. 3A-7) body contact regions 28 may be formed having, along the X-axis, a dimension smaller than the dimension d_{B}″, so that each body contact region 28 (or the single body contact region 28 if only one is present) is, in top-view on the XY-plane, separated from the gate regions 22 by a portion of the source region 24, of N-type.

Furthermore, the present disclosure applies, in a per se evident manner, to P-channel devices. In this case, the semiconductor body 21 is of N-type, the source and drain regions 24, 26 are of P-type, and the body contact region 28 is of N-type.

Furthermore, the present disclosure applies to vertical conduction devices, wherein the drain region 26 extends on the back of the semiconductor body 21, i.e., at a side of the semiconductor body 21 opposite, along the Z-axis, to the side 21a.

Furthermore, the semiconductor body 21 may include a substrate and an epitaxial layer grown over the substrate, wherein the epitaxial layer and the substrate may have conductivities different from each other. The source, drain and body contact regions 24, 26, 28 are formed at a surface of the epitaxial layer.

Furthermore, the present disclosure applies to devices which have a single gate region 22 (in this case the value d_{B}″ corresponds to the maximum width, along the X-axis, of the body contact region(s) 28).

Furthermore, the present disclosure applies to devices with trench-gate electrodes (Trench-MOS transistors).

An electronic device (20), is summarized as including: a semiconductor body (21) having a surface (21a), having a first electrical conductivity (P) and a first doping value; at least one first gate region (22), extending on the surface (21a); one or more source regions (24), having a second electrical conductivity (N) opposite to the first electrical conductivity (P), extending in the semiconductor body (21) at the surface (21a) and at a first side of the gate region (22); at least one first body contact region (28), having the first electrical conductivity (P) and a second doping value greater than the first doping value, extending in the semiconductor body (21) at the surface (21a) and at the first side of the gate region (22), wherein the first gate region (22) has the shape of a stripe with main extension along a first direction (Y), and wherein at least one portion of the first body contact region (28) has a tapered shape along said first direction (Y), said one or more source regions (24) being adjacent to, and at least partially surrounding, said first body contact region (28).

Said first body contact region (28) may be aligned with, or at least partly superimposed on, the gate region (22) at the first side of the gate region (22).

Said first body contact region (28) may extend at a distance from the first side of the gate region (22), said one or more source regions (24) extending between said first body contact region (28) and the first side of the gate region (22).

Said first body contact region (28) may have a polygonal shape, including quadrangular, pentagonal, hexagonal shape, and a vertex of said polygonal shape may face directly towards the gate region (22).

Said first body contact region (28) may have a rhombus shape, wherein a first diagonal of said rhombus is orthogonal to the first direction (Y), and a second diagonal of said rhombus is parallel to the first direction (Y); alternatively, wherein said first body contact region (28) has a rhombus shape, wherein a first diagonal of said rhombus forms, with the first direction (Y), an angle greater than 0° and smaller than 90°.

Said first body contact region (28) has a circular or oval or closed curvilinear shape.

The electronic device further includes at least one second body contact region (28), having the first electrical conductivity (P) and the second doping value, extending in the semiconductor body (21) at the surface (21a) and at the first side of the gate region (22), wherein at least one portion of the second body contact region (28) has a tapered shape along said direction (Y), wherein at least one of said one or more source regions (24) is adjacent to, and at least may partially surround, said second body contact region (28).

The first and the second body contact regions (28) extend adjacent to each other.

The first and the second body contact regions (28) extend at a first distance (SP) from each other along said first direction (Y) and are separated from each other, along said first direction (Y), by at least one of said one or more source regions (24).

The electronic device further includes a second gate region (22), extending on the surface (21a) at a second distance (d_{B}″) from the first gate region (22), said second distance being along a second direction (X) orthogonal to the first direction (Y), wherein the second gate region (22) has the shape of a stripe with main extension along the first direction (Y) and is parallel to the first gate region (22).

Said one or more source regions (24) and the first body contact region (28) are completely contained within a portion (30) of the semiconductor body (21) between the first and the second gate regions (22).

Also the second body contact region (28) is completely contained within said portion (30).

The electronic device further includes an electrical coupling layer (42), of a Silicide of a metal, extending with electrical continuity on the one or more source regions (24) and on the first body contact region (28).

The electronic device further includes a drain region (26) extending in the semiconductor body (21) at the surface (21a) and at a second side of the gate region (22) opposite to the first side along a direction orthogonal to the first direction (Y), the drain region (26) having the second electrical conductivity.

The first body contact region (28) and a plurality of further body contact regions (28) are arranged in succession with a periodicity along said direction (Y) at the first side of the gate region (22), each further body contact region having the first electrical conductivity (P) and the second doping value, and extending in the semiconductor body (21) at the surface (21a).

Said body contact region (28) has a first dimension, along a second direction (X) orthogonal to the first direction (Y) and to a first height of the first direction (Y), having a first value, and a second dimension, along the second direction (X) orthogonal to the first direction (Y) and to a second height, different from the first height, of the first direction (Y), having a second value different from the first width value.

A method of manufacturing an electronic device (20), is summarized as including the steps of: forming a first gate region (22) on a surface (21a) of a semiconductor body (21) having a first electrical conductivity (P) and a first doping value, wherein the first gate region (22) has the shape of a stripe with main extension along a direction (Y); forming a first implant mask (50) on the surface (21a), said first implant mask (50) including at least one portion having a tapered shape along said direction (Y) and extending at a first side of the gate region (22); implanting, in the semiconductor body (21) at the first surface (21a) and at the first side of the gate region (22), doping species having a second electrical conductivity (N) opposite to the first electrical conductivity (P), forming one or more source regions; removing the first implant mask (50) and forming a second implant mask (52) on the surface (21a), said second implant mask (52) having a complementary shape with respect to the first implant mask (50); and implanting, in the semiconductor body (21) at the first surface (21a), doping species having the first electrical conductivity (P), thus forming one or more body contact regions (28) having a doping density greater than a doping density of the semiconductor body (21).

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An electronic device, comprising:
a semiconductor body having a surface, having a first electrical conductivity and a first doping value;
at least one first gate region, extending on the surface;
one or more source regions, having a second electrical conductivity opposite to the first electrical conductivity, extending in the semiconductor body at the surface, at a first side of the gate region, and for a first depth;
at least one first body contact region, having the first electrical conductivity and a second doping value greater than the first doping value, extending in the semiconductor body at the surface, at the first side of the gate region, and for a second depth greater than the first depth,
wherein the first gate region has the shape of a stripe with main extension along a first direction,
and wherein at least one portion of the first body contact region has a tapered shape along said first direction,
said one or more source regions being adjacent to, and at least partially surrounding, said first body contact region.

2. The electronic device according to claim 1, wherein said first body contact region is aligned with, or at least partly superimposed on, the gate region at the first side of the gate region.

3. The electronic device according to claim 1, wherein said first body contact region extends at a distance from the first side of the gate region,
said one or more source regions extending between said first body contact region and the first side of the gate region.

4. The electronic device according to claim 1, wherein said first body contact region has a polygonal shape, including quadrangular, pentagonal, hexagonal shape, and wherein a vertex of said polygonal shape faces directly towards the gate region.

5. The electronic device according to claim 1, wherein said first body contact region has a rhombus shape, wherein a first diagonal of said rhombus is orthogonal to the first direction, and a second diagonal of said rhombus is parallel to the first direction;
alternatively, wherein said first body contact region has a rhombus shape, wherein a first diagonal of said rhombus forms, with the first direction, an angle greater than 0° and smaller than 90°.

6. The electronic device according to claim 1, wherein said first body contact region has a circular or oval or closed curvilinear shape.

7. The electronic device according to claim 1, further comprising at least one second body contact region, having the first electrical conductivity and the second doping value, extending in the semiconductor body at the surface and at the first side of the gate region,
wherein at least one portion of the second body contact region has a tapered shape along said direction, wherein at least one of said one or more source regions is adjacent to, and at least partially surrounds, said second body contact region.

8. The electronic device according to claim 7, wherein the first and the second body contact regions extend adjacent to each other.

9. The electronic device according to claim 7, wherein the first and the second body contact regions extend at a first distance from each other along said first direction and are separated from each other, along said first direction, by at least one of said one or more source regions.

10. The electronic device according to claim 1, further comprising a second gate region, extending on the surface at a second distance from the first gate region, said second distance being along a second direction orthogonal to the first direction,
wherein the second gate region has the shape of a stripe with main extension along the first direction and is parallel to the first gate region.

11. The electronic device according to claim 1, wherein said one or more source regions and the first body contact region are completely contained within a portion of the semiconductor body comprised between the first and the second gate regions.

12. The electronic device according to claim 10, wherein also the second body contact region is completely contained within said portion.

13. The electronic device according to claim 1, further comprising an electrical coupling layer, of a Silicide of a metal, extending with electrical continuity on the one or more source regions and on the first body contact region.

14. The electronic device according to claim 1, further comprising a drain region extending in the semiconductor body at the surface and at a second side of the gate region opposite to the first side along a direction orthogonal to the first direction, the drain region having the second electrical conductivity.

15. The electronic device according to claim 1, wherein the first body contact region and a plurality of further body contact regions are arranged in succession with a periodicity along said direction at the first side of the gate region,
each further body contact region having the first electrical conductivity and the second doping value, and extending in the semiconductor body at the surface.

16. The electronic device according to claim 1, wherein said body contact region has:
a first dimension, along a second direction orthogonal to the first direction and to a first height of the first direction, having a first value, and
a second dimension, along the second direction orthogonal to the first direction and to a second height, different from the first height, of the first direction, having a second value different from the first width value.

17. A method of manufacturing an electronic device, comprising the steps of:
forming a first gate region on a surface of a semiconductor body having a first electrical conductivity and a first doping value, wherein the first gate region has the shape of a stripe with main extension along a direction;
forming a first implant mask on the surface, said first implant mask including at least one portion having a tapered shape along said direction and extending at a first side of the gate region;
implanting, in the semiconductor body at the first surface and at the first side of the gate region, doping species having a second electrical conductivity opposite to the first electrical conductivity, forming one or more source regions;
removing the first implant mask and forming a second implant mask on the surface, said second implant mask having a complementary shape with respect to the first implant mask; and
implanting, in the semiconductor body at the first surface, doping species having the first electrical conductivity, thus forming one or more body contact regions having a doping density greater than a doping density of the semiconductor body.

18. The method of claim 17, wherein the first implant mask includes at least one polygonal shape, including quadrangular, pentagonal, hexagonal shape, and wherein a vertex of said polygonal shape faces directly towards the formed first gate region.

19. The method of claim 17, wherein the first implant mask includes at least one circular shape.

20. A device, comprising:
a semiconductor body having a first electrical conductivity, and a first doping value;
a first surface on the semiconductor body, the first surface being between a first gate region and a second gate region, the first surface having a first edge at the first gate region;
a plurality of source regions on the first surface, each source region having a second electrical conductivity opposite to the first electrical conductivity, extending in a first direction traverse to the first surface, and for a first depth;
a plurality of body contact regions on the first surface, each body contact region having the first electrical conductivity and a second doping value greater than the first doping value, extending in the first direction for a second depth greater than the first depth, wherein the plurality of body contact regions contact the first edge at a plurality of first vertices and the plurality of source regions contacts the entire first edge except the plurality of first vertices.
